(19) United States
(12) Patent Application Publication
(10) Pub. No.: US 2003/0048838 A1
(43) Pub. Date: Mar. 13, 2003

(54) Two-stage equalization apparatus and method using same

(75) Inventors: Thomas A. Sexton, Fort Worth, TX (US); Hannu Vilpponen, Irving, TX (US)

Correspondence Address: Nokia Inc, 6000 Connection Drive, Mail Stop 1:4-755, Irving, TX, 75039, US

(73) Assignee: Nokia Corporation, Espoo (FI)

(21) Appl. No.: 09/952,241

(22) Filed: Sep. 11, 2001

(51) Int. Cl. H03H 7/30

(52) U.S. Cl. 375/229

(57) ABSTRACT

A method and apparatus for reducing a number of calculations during equalization is disclosed. A burst is processed using weak equalization and with strong equalization when a predetermined criteria is met. By performing weak equalization rather than strong equalization when a predetermined condition is met the number of calculation may be reduced for most bursts. In addition, in one embodiment of the present invention, if strong equalization fails, then turbo equalization is used. Equalizer selection for subsequent bursts in block may occur after review of the equalization results of the first burst in a block.

### CROSS-REFERENCE TO OTHER PATENT APPLICATIONS

The following co-pending patent application of common assignee contains some common disclosure: U.S. patent application Ser. No. 09/790,468, filed on Feb. 22, 2001, which is incorporated herein by reference in its entirety.

### BACKGROUND

This invention relates in general to digital wireless communication using equalization for overcoming the effects of multi-path fading and interference, and more particularly to a two-stage equalizer and method for reducing the average number of calculations required in an equalization process.

An increasingly mobile workforce is driving growth for handheld devices. People need to stay in contact with the office, and the PDA (personal digital assistant) and mobile phone are lightweight, powerful and economical. Mobile e-commerce (M-Commerce) is already available in limited fashion. Wireless standards continue to evolve toward seamless web access from any point on the globe with one integrated mobile device. Moreover, cellular phones are beginning to transform personal computing.

EDGE involves a new modulation scheme that is more bandwidth efficient than the Gaussian prefiltered minimum shift keying (GMSK) modulation scheme used in the GSM standard. It provides a promising migration strategy for HSCSD (High Speed Circuit Switched Data) and GPRS (General Packet Radio Service). The technology defines a new physical layer: 8-phase shift keying (8-PSK) modulation, instead of GMS K. 8-PSK enables each pulse to carry 3 bits of information versus GMSK's 1-bit-per-pulse rate.

EDGE retains other existing GSM parameters including a 4.615-ms frame length, eight timeslots per frame, and a 270.833-kHz symbol rate. GSM's 200-kHz channel spacing is also maintained in EDGE, allowing the use of existing spectrum bands. This fact is likely to encourage deployment of EDGE technology on a global scale.

Owing to the well known and accepted advantages of digital transmission, especially in its robustness to interference and noise, and to recent advances in low bit-rate speech coding, post-second generation digital cellular radio. There are, however, many challenging problems confronting designers. Most of these problems are grouped into the two categories of limited bandwidth and multipath propagation.

To accommodate many mobile users accessing a limited radio bandwidth in a given service area, it is necessary to reuse radio frequency channels. This multiple user accommodation is achieved through the use of the cellular concept. Cells represent subdivisions of a service area which could be, for example, a city or an entire country. A mobile unit communicates with a base station located within the mobile's cell, the frequency channels for which may be reused by mobiles and base stations in other cells. Because radio signals become weaker as mobiles move away from their base stations and transmission paths may be shadowed by large obstructions, signal-to-CC ratios can fall to very low values for typical cell designs and reuse plans.

Mobile-to-base transmission (and vice versa) takes place over many paths due to scattering of radio waves by the terrain, buildings, vehicles, and other objects in the environment. The amplitude of the resultant received signal depends on the relative position of the mobile (and the scatterers) with respect to the base station, and on the transmitted frequency.

To counter InterSymbol Interference (ISI), equalization techniques can be employed in the receiver. Channel equalization is the process of compensating for the effect of the physical channel between a transmitter and a receiver on the information exchanged. In conventional linear equalization, for example, the received signal is passed to an adaptive filter that attempts to flatten out the channel frequency response while avoiding noise enhancement. Various equalizer algorithms are used for eliminating ISI. Equalizers are designed to detect the source signal by reducing the interference due to other undesired symbols.

Channel equalization is an important area in communications as it can greatly improve the quality of the information once it has been received. Unless the information received can be decoded without error, a data block must be retransmitted. Improvement in the information received leads to higher quality transmission which in turn leads to more efficient communication as retransmission may not be as necessary. Prior equalization techniques have usually concentrated on the optimization of the retransmission strategy.

One technique for decreasing retransmissions in packet data systems is the incremental redundancy (IR) technique. The IR technique is based on the repeated transmissions of the same data block in case of failed decoding of the original block. If the block is erroneous, the conventional IR method is to request for a retransmission and replace or combine the original block with the new one. The major drawback is the lower data throughput of the system due to the retransmissions. The system also suffers from the possible delays because the retransmission requests have to be handled in the upper layers before the retransmission can take place.

Because these prior methods have required the retransmission of the block if the decoding is unsuccessful, additional methods have been developed to reduce the number of retransmissions. One iterative technique does not make the request for retransmission immediately, but instead, tries to correct the bit errors in an iterative fashion. The soft-outputs from the channel decoder are used as a priori information in the equalization of the next iteration round. As the receiver starts to receive a new block after the old one is fully received, a temporary buffer in front of the equalizer stores new sample for a while. Thus, the new samples are not interfering with the iterative processing of the previous block. For example, the maximum buffer size may be ¼ of the block length, which ensure some time to iterate the previous block, but also it does not delay the continuous reception process at the receiver. The decision element (iterate or not) after failed CRC checking takes into account how full the buffer is currently and/or whether there is otherwise time to iterate again. In addition, the number of earlier iterations may be used as a criteria for determining whether to iterate or not.

In many cases, a turbo equalizer is able to correct the failed block in a few iterations, which improves the data throughput as the retransmission of the corrected block is avoided. The equalization and channel decoding may be performed quite fast, so there is often enough time to iterate a few times before processing the next block. Nevertheless, the equalization process requires a large number of calculations.

It can be seen that there is a need for an effective equalization and a method for reducing the average number of calculations required in an equalization process.

### SUMMARY OF THE INVENTION

To overcome the limitations in the prior art described above, and to overcome other limitations that will become apparent upon reading and understanding the present specification, the present invention discloses a two-stage equalizer and method for reducing the average number of calculations required in an equalization process.

The present invention solves the above-described problems by performing weak equalization rather than strong equalization if a predetermined condition is met.

A method in accordance with the principles of the present invention includes processing bursts using weak equalization when a predetermined criteria is met.

In another embodiment of the present invention, a two-stage equalizer for reducing a number of calculations during equalization is disclosed. The two-stage equalizer includes a weak equalizer for equalizing a first burst, a processor for determining whether predetermined criteria are met; and a strong equalizer for equalizing a subsequent burst when the predetermined criteria is met.

In another embodiment of the present invention, another two-stage equalizer for reducing a number of calculations during equalization is disclosed. The two-stage equalizer includes weak equalizing means for equalizing a first burst and processing means for determining whether predetermined criteria are met and strong equalizing means for equalizing a subsequent burst when the predetermined criteria is met.

In another embodiment of the present invention, a computer-readable memory for directing a computer to perform an two-stage equalizer method for reducing a number of calculations during equalization is disclosed. The computer readable memory includes a first portion to direct the computer to process a first burst using weak equalization and a second portion to direct the computer to process a subsequent burst using strong equalization when a predetermined criteria is met.

In another embodiment of the present invention, computer data signal embodied in a carrier wave is disclosed. The computer data signal includes instructions for instructing a computer to process a first burst using weak equalization and to process a subsequent burst using strong equalization when a predetermined criteria is met.

These and various other advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there are illustrated and described specific examples of an apparatus in accordance with the invention.

### BRIEF DESCRIPTION OF THE DRAWINGS

Referring now to the drawings in which like reference numbers represent corresponding parts throughout:

FIG. 1 is a block diagram illustrative of a digital communications system;

FIG. 2 is a block diagram illustrative of a demodulator in accordance with an embodiment of the present invention;

FIG. 3 is a flow diagram illustrative of a demodulator suppressing intersymbol interference in the context of high-speed digital communication channels according to an embodiment of the present invention;

FIG. 4 is illustrative of the deinterleaver buffer which deinterleaves the soft data values from the equalized data frame;

FIG. 5 is a plot of the frame error rate versus the energy-per-bit to noise density ratio (Eb/No) for two equalizers;

FIG. 6 is a flow chart illustrative of an equalization method according to an embodiment of the present invention; and

FIG. 7 is a flow chart illustrative of an equalization method according to another embodiment of the present invention.

### DETAILED DESCRIPTION OF THE INVENTION

In the following description of the exemplary embodiment, reference is made to the accompanying drawings which form a part hereof, and in which is shown by way of illustration the specific embodiment in which the invention may be practiced. It is to be understood that other embodiments may be utilized as structural changes may be made without departing from the scope of the present invention.

The present invention provides a two-stage equalizer and method for reducing the average number of calculations required in an equalization process. By performing weak equalization rather than strong equalization when a predetermined condition is met the number of calculations may be reduced for most bursts. In addition, in one embodiment of the present invention, if strong equalization fails, then turbo equalization is used. Equalizer selection for subsequent bursts in a block may occur after review of the equalization results of the first burst in a block.

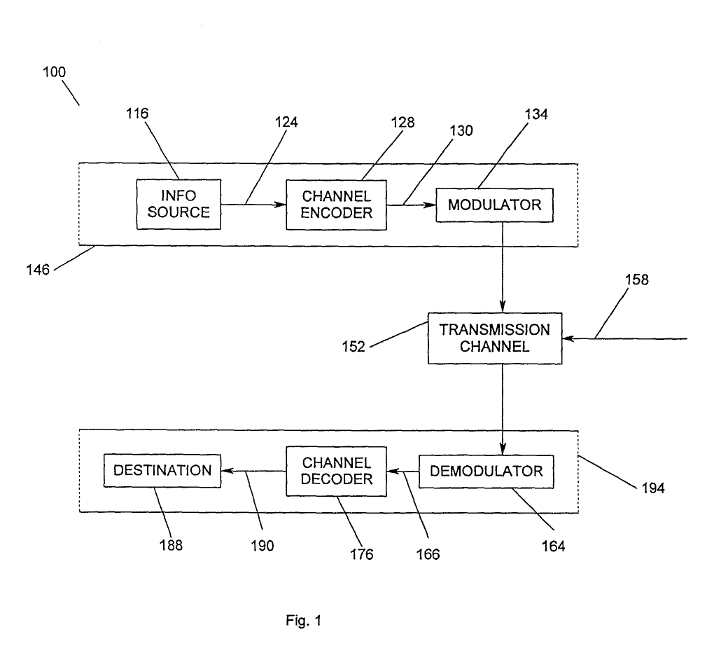

FIG. 1 illustrates a block diagram of a digital communications system 100. Communication system 100 is operable to transmit and to receive discretely encoded communication signals. An information source 116 is representative of the source of a communication signal. The communication signal generated by information source 116 is supplied, by way of line 118, to channel encoder 128. Channel encoder 128 encodes the signal applied thereto according to a coding technique. Channel encoder 128 may, for example, comprise a block or convolutional encoder. Channel encoder 128 is operable to increase the redundancy of the discrete signal applied thereto on line 124. By increasing the redundancy of the discrete signal, transmission errors and distortion introduced upon the signal during transmission are less likely to prevent a receiver portion of communication system 100 from detecting an actual, transmitted signal.

The encoded signal generated by channel encoder 128 is applied on line 130 to modulator 134. Modulator 134 modulates the encoded communication signal applied thereto according to a modulation technique. Modulator 134 generates a modulated carrier signal formed of the encoded signal applied thereto and a carrier signal. Information source 116, channel encoder 128, and modulator 134 together comprise a transmitter 146 and indicated by the block shown in hatch which encompasses such elements.

The modulated carrier signal generated by modulator 134 of transmitter 146 is transmitted upon a transmission channel, here indicated by block 152. Because an actual, transmission channel is not an interference-free channel, interference (due, e.g., to noise, intersymbol interference and Rayleigh fading) is introduced upon the modulated carrier signal when the modulated carrier signal is transmitted thereupon. Such interference is indicated in the figure by line 158 applied to transmission channel 152.

The modulated carrier signal transmitted by transmitter 146 upon transmission channel 152 is received by a receiver. The receiver includes demodulator 164 which is operative to demodulate the modulated carrier signal, once received by the receiver. Demodulator 164 generates a demodulated signal on line 166 which is applied to channel decoder 176. Channel decoder 176 corresponds to channel encoder 128 of transmitter portion 146 and is operative in a manner reverse with that of channel encoder 128, thereby to decode the encoded signal applied thereto by demodulator 164. Channel decoder 176 generates a decoded signal to be forward to destination 188 on line 190. Demodulator 164, channel decoder 176, and destination 188 together comprise the receiver, here referred to generally by reference numeral 194, indicated in the figure by the block shown in hatch.

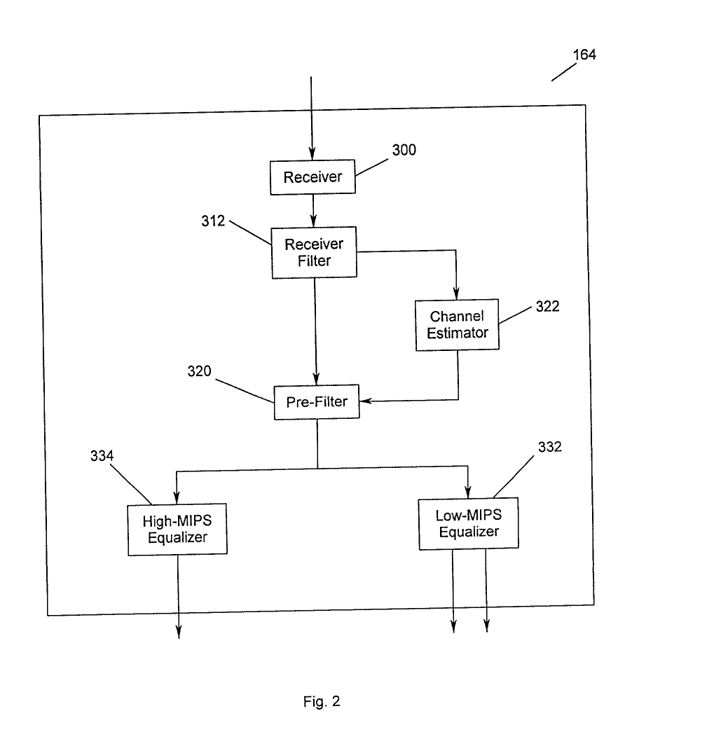

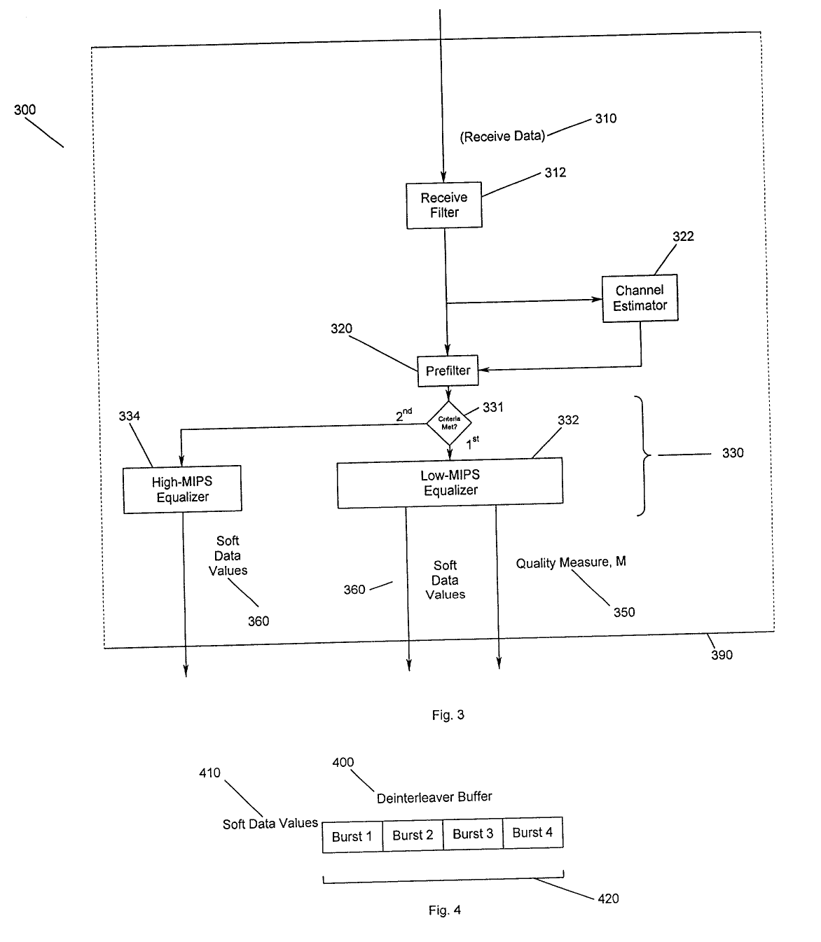

FIG. 2 is a block diagram illustrative of the demodulator in accordance with an embodiment of the present invention. FIG. 3 is a flow diagram illustrative of the processing of a signal by a demodulator 164 in accordance with another embodiment of the invention wherein the blocks of FIG. 2 are discrete components.

FIGS. 2 & 3 illustrates a receiver 300 suppressing intersymbol interference in the context of high-speed digital communication channels according to the present invention. A burst of received data 310 is filtered at the receive filter 312. A prefilter 320 provides complex symbol-spaced samples at the input to the equalizer 330. Coefficients for the prefilter 320 are obtained from channel estimation 322. During the equalization of the burst, a metric 350 is obtained, such as from the sum of the squared errors. Preferably, error may be defined as the Euclidean distance from the equalized sample to the nearest modulation constellation point.

A determination is made whether predetermined criteria are met. If the metric is less than a predetermined threshold, then the equalization is deemed successful and the burst is passed on for further processing. If the metric is greater than the predetermined threshold, the equalization is estimated to have failed and the burst is processed with the high-MIPs, high-performance equalization scheme 334. The equalized bursts are formed into an entire RLC block of soft values 410 and passed on for decoding. In most cases, the RLC block 360 will decode successfully. In the fraction of cases which fail, any bursts which have only been processed by the weak equalization scheme 332 are re-processed using the strong equalization scheme 334 and then the entire block is decoded. The RLC block may be four bursts long.

As stated above, the equalizer, as well as prefilter, channel estimator and other components, may be implemented in DSP (digital signal processor) code or in an application specific integrated circuit (ASIC). When the equalizer, prefilter, channel estimator or other components are implemented in DSP (digital signal processor) may perform the functions of one or more of the components. Alternatively, the components may be discrete components as shown in FIG. 3. Other variations and modifications may be made without departing from the spirit and scope of the present invention.

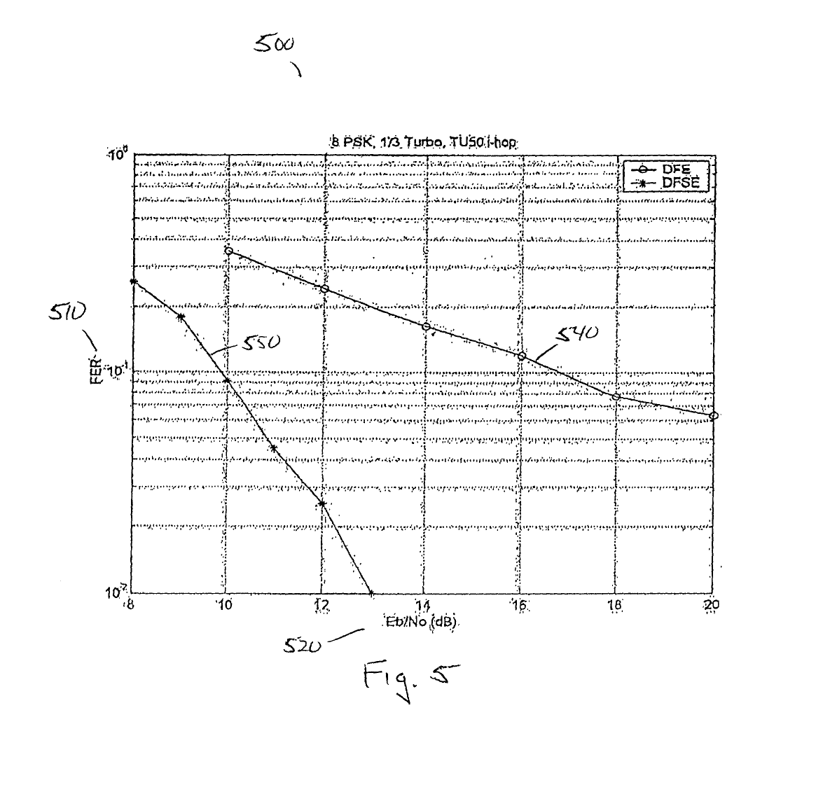

FIG. 4 is illustrative of the deinterleaver buffer 400 which deinterleaves the soft data values 410 from the equalized data frame. The deinterleaver buffer 400 stores the soft data values 410 for a block and restores the interleaved symbols to the original order.

FIG. 5 is a plot 500 of the frame error rate 510 versus the energy-per-bit to noise density ratio (Eb/No) 520 for two equalizers. In FIG. 5, the performance of a “weak” equalizer (DFE) 540 is shown. In addition, FIG. 5 shows the performance of a “strong” equalizer 550 (DFSE, and MLSE hybrid structure) on a very typical cellular channel. The strong equalizer 550 has a much lower frame error rate for a given Eb/No value, but at higher complexity. Most calls will operate somewhere in the Eb/No region shown in FIG. 5.

According to the present invention, a two-stage equalizer and method for reducing the average number of calculations required in an equalization process is provided.

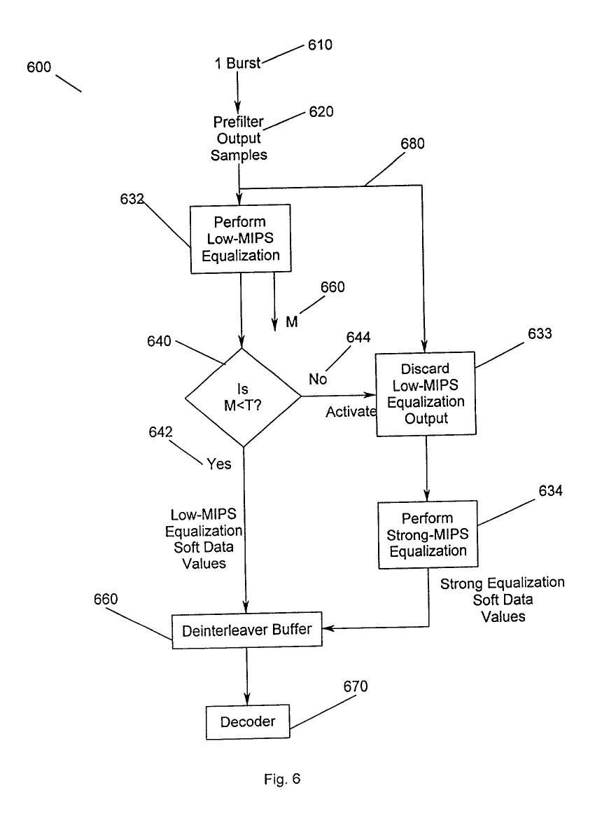

FIG. 6 is illustrative of a flow chart 600 for an embodiment of an equalization method according to the present invention. A burst 610 is processed through a prefilter to produce prefilter output samples 620. The samples are equalized using a low-MIPS, low-performance equalizer 632 such as the DFE. During the equalization of the burst, a metric 650, e.g., the sum of the squared errors is developed to get the metric M. The metric 650 is compared 640 to a predetermined threshold, T. If the metric is less than the threshold 642, then the equalization is deemed successful and the burst is passed on for further processing. If the metric is greater than the predetermined threshold 644, the equalization is estimate to have failed, the low-MIPS equalization output is discarded 633, and the burst is processed with a high-MIPs, high-performance equalization scheme 634, such as MLSE or a degenerate hybrid thereof, such as DDFSE. The equalized bursts are formed into an entire RLC block of soft values in the deinterleaver buffer 660 and then passed on for decoding 670.

In most cases, the RLC block will decode successfully. In the fraction of cases which fail, any bursts which have only been processed by the weak equalization scheme 632 may be re-processed using the strong equalization scheme 634 and then the entire block is decoded 670. Moreover, there are a multitude of variations possible without departing from the scope of the present invention. Soft values could be retained after the first weak equalizer pass. Also, the scheme might only be employed if the estimated energy-per-bit to noise density ratio (Eb/No) is above a predetermined value 680. Further, any iteration metric other than M could be used to trigger the strong equalization step before decoding.

Thus, processing for most bursts is simplified. For those bursts which the metric is less than the predetermined threshold, processing is slightly increased for those bursts compared to a full MLSE, DDFSE or other strong equalization. For example, if Eb/No is greater than 17 dB, the FER for the DFE is less than 0.1 for the TU50 channel shown in FIG. 5, (different numbers for other channels). Thus, for this example, 90% of the time only the weak equalizer is employed. This assumes that the metric closely tracks bursts which will contribute to frame errors.

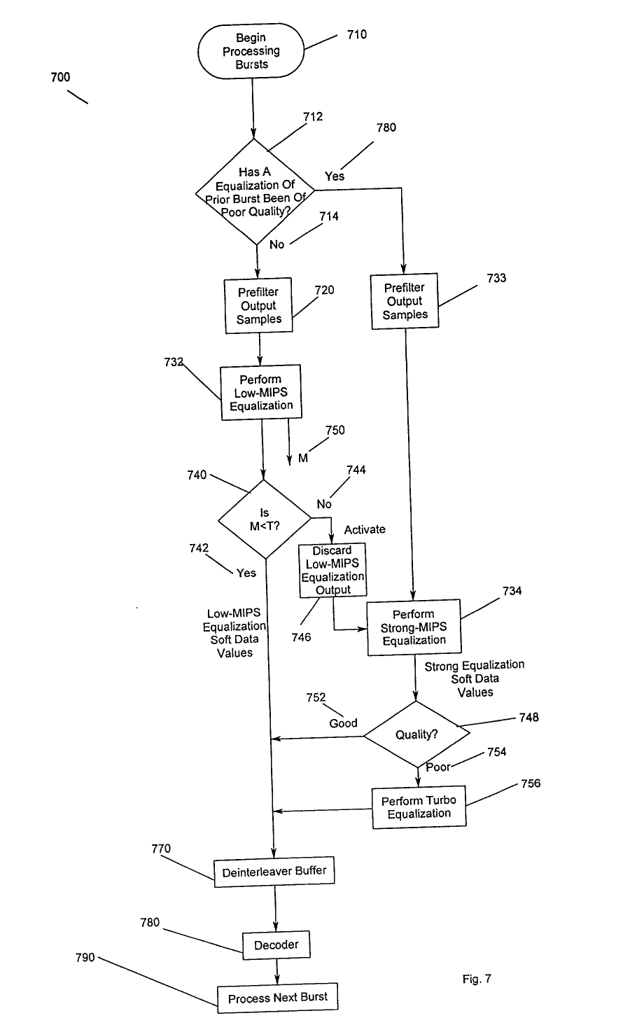

FIG. 7 illustrates a flow chart for an embodiment of an equalization method according to the present invention. Processing of bursts is initialized 710. A determination is made whether equalization of a prior burst was of poor quality 712. If yes 760, then the burst is prefiltered 733 and strong equalization is used 734. If not 714, the burst is processed through a prefilter to produce prefilter output samples 720. The samples are equalized using a low-MIPS, low-performance equalizer 732 such as the DFE. During the equalization of the burst, a metric 750, e.g., the sum of the squared errors is developed to get the metric M. The metric 750 is compared 740 to a predetermined threshold, T. If the metric is less than the threshold 742, then the equalization is deemed successful and the burst is passed on for further processing. If the metric is greater than the predetermined threshold 744, the equalization is estimate to have failed, the low-MIPS equalization output is discarded 746, and the bursts is processed with a high-MIPs, high-performance equalization scheme 734, such as MLSE or a degenerate hybrid thereof, such as DDFSE.

The quality of the strong equalization is analyzed 750. If it is of good quality 752, the equalized bursts are formed into an entire RLC block of soft values in the deinterleaver buffer 770 and then passed on for decoding 780. Then the next burst is processed 790. If the quality of the strong equalization is poor 754, turbo equalization is used 756. Full turbo equalization is employed with the feeding-back of soft values from the decoder to the strong equalizer 734. An example of turbo equalization may be found in co-pending application assigned to common assignee and given U.S. patent application Ser. No. 09/790,468, filed on Feb. 22, 2001.

Software implementing embodiments of the present invention may be tangibly embodied in a computer-readable medium or carrier, e.g. one or more of the fixed and/or removable data storage devices or other data storage or data communications devices and carrier waves. A computer program expressing the processes embodied on the removable data storage devices may be loaded into the memory or into the equalizer, e.g., in a processor such as a microprocessor, digital signal processor (DSP) or the like to configure the equalizer for execution. The equalizer, as well as prefilter, channel estimator and other components, may be implemented in DSP (digital signal processor) code or in an application specific integrated circuit (ASIC). The computer program comprise instructions which, when read and executed by the equalizer, causes the equalizer to perform the steps necessary to execute the steps or elements of the present invention

The foregoing description of the exemplary embodiment of the invention has been presented for the purposes of illustration and description. It is not intended to be exhaustive or to limit the invention to the precise form disclosed. Many modifications and variations are possible in light of the above teaching. It is intended that the scope of the invention be limited not with this detailed description, but rather by the claims appended hereto.

What is claimed is:

1. A method for reducing a number of calculations during equalization, comprising;
processing a burst using weak equalization; and
processing a burst using strong equalization when a predetermined criteria is met.

2. The method of claim 1, wherein the processing the burst using weak equalization comprises using weak equalization to process the first burst and continuing to use weak equalization for a plurality of subsequent bursts when the weak equalization is of good quality.

3. The method of claim 2, wherein the plurality of subsequent bursts are within an RLC block.

4. The method of claim 3, wherein the RLC block is four bursts long.

5. The method of claim 2, wherein the predetermined criteria indicates the weak equalization is of poor quality and the processing the plurality of subsequent bursts using strong equalization comprises using strong equalization to process a plurality of bursts subsequent to the first burst processed with weak equalization resulting in poor quality.

6. The method of claim 5, wherein the plurality of subsequent bursts are within an RLC block.

7. The method of claim 6, wherein the RLC block is four bursts long.

8. The method of claim 1, wherein the predetermined criteria indicates the weak equalization is of poor quality and the processing a burst using strong equalization comprises using strong equalization to process a plurality of bursts subsequent to the burst processed with weak equalization resulting in poor quality.

9. The method of claim 1, wherein the predetermined criteria comprises a comparison of a metric obtained from weak equalization to a first predetermined threshold.

10. The method of claim 9, wherein processing with weak equalization is performed when the metric is greater than the predetermined threshold.

11. The method of claim 10, wherein processing with strong equalization is preformed when the metric is less than the predetermined threshold.

12. The method of claim 9, wherein processing with strong equalization is preformed when the metric is less than the predetermined threshold.

13. The method of claim 9, wherein the metric is obtain from a calculation of a sum of the squared errors during weak equalization.

14. The method of claim 1, wherein the predetermined criteria comprises a determination that an estimated energy-per-bit to noise ratio is greater that a predetermined value.

15. The method of claim 1, wherein the predetermined criteria comprises a determination that a metric obtained from the weak equalization is greater that a predetermined threshold.

16. The method of claim 1, further comprising prefiltering a received burst of data to produce samples for equalization.

17. The method of claim 1, wherein the weak equalization comprises decision feedback equalization.

18. The method of claim 1, wherein the strong equalization comprises at least one of maximum likelihood sequence estimator and delayed-decision-feedback sequence estimation.

19. The method of claim 1, further comprising performing full turbo equalization using soft values fed-back from a decoder when the strong equalization fails.

20. A two-stage equalizer for reducing a number of calculations during equalization, comprising;
a weak equalizer for equalizing a first burst;
a processor for determining whether predetermined criteria are met; and
a strong equalizer for equalizing a subsequent burst when the predetermined criteria is met.

21. The two-stage equalizer of claim 20, wherein the weak equalizer is used to process the first burst and subsequent bursts when the weak equalization for the first burst is of good quality.

22. The two-stage equalizer of claim 21, wherein the plurality of subsequent bursts are within an RLC block.

23. The two-stage equalizer of claim 22, wherein the RLC block is four bursts long.

24. The two-stage equalizer of claim 21, wherein the predetermined criteria indicates the weak equalization is of poor quality and the strong equalizer is used to process a plurality of bursts subsequent to the first burst processed with weak equalization resulting in poor quality.

25. The two-stage equalizer of claim 24, wherein the plurality of subsequent bursts are within an RLC block.

26. The two-stage equalizer of claim 25, wherein the RLC block is four bursts long.

27. The two-stage equalizer of claim 20, wherein the predetermined criteria indicates the weak equalization is of poor quality and the strong equalizer is used to process a plurality of bursts subsequent to the first burst processed with weak equalization resulting in poor quality.

28. The two-stage equalizer of claim 20, wherein the predetermined criteria comprises a comparison of a metric obtained from weak equalization to a first predetermined threshold.

29. The two-stage equalizer of claim 28, wherein the weak equalizer is used when the metric is greater than the predetermined threshold.

30. The two-stage equalizer of claim 29, wherein the strong equalizer is used when the metric is less than the predetermined threshold.

31. The two-stage equalizer of claim 28, wherein the strong equalizer is used when the metric is less than the predetermined threshold.

32. The two-stage equalizer of claim 28, wherein the metric is obtain from a calculation of a sum of the squared errors performed by the weak equalizer.

33. The two-stage equalizer of claim 20, wherein the predetermined criteria comprises a determination that an estimated energy-per-bit to noise ratio is greater that a predetermined value.

34. The two-stage equalizer of claim 20, wherein the predetermined criteria comprises a determination that a metric obtained from the weak equalization is greater that a predetermined threshold.

35. The two-stage equalizer of claim 20, wherein the weak equalizer comprises a decision feedback equalizer.

36. The two-stage equalizer of claim 20, wherein the strong equalizer comprises one of a maximum likelihood sequence estimator or a delayed-decision-feedback sequence estimator.

37. The two-stage equalizer of claim 20, further comprising a full turbo equalizer that uses soft values fed-back from a decoder when the strong equalization fails.

38. A two-stage equalizer for reducing a number of calculations during equalization, comprising;
weak equalizing means for equalizing a burst;
processing means for determining whether predetermined criteria are met; and
strong equalizing means for equalizing a burst when the predetermined criteria is met.

39. A computer-readable memory for directing a computer to perform a method for reducing a number of calculations during equalization when used by the computer, comprising:
a first portion to direct the computer to process a first burst using weak equalization; and
a second portion to direct the computer to process a subsequent burst using strong equalization when a predetermined criteria is met.

40. The computer-readable memory of claim 39, wherein the first portion for directing the computer to process the first burst using weak equalization directs the computer to use weak equalization to process the first burst and continuing to use weak equalization for subsequent bursts when the weak equalization is of good quality.

41. The computer-readable memory of claim 40, wherein the plurality of subsequent bursts are within an RLC block.

42. The computer-readable memory of claim 41, wherein the RLC block is four bursts long.

43. The computer-readable memory of claim 40, wherein the predetermined criteria indicates the weak equalization is of poor quality and the second portion for directing the computer to process the subsequent burst using strong equalization directs the computer to use strong equalization to process a plurality of bursts subsequent to the first burst processed with weak equalization resulting in poor quality.

44. The computer-readable memory of claim 43, wherein the plurality of subsequent bursts are within an RLC block.

45. The computer-readable memory of claim 44, wherein the RLC block is four bursts long.

46. The computer-readable memory of claim 39, wherein the predetermined criteria indicates the weak equalization is of poor quality and the second portion for directing the computer to process the subsequent burst using strong equalization directs the computer to use strong equalization to process a plurality of bursts subsequent to the first burst processed with weak equalization resulting in poor quality.

47. The computer-readable memory of claim 39, wherein the first predetermined criteria comprises a comparison of a metric obtained from weak equalization to a first predetermined threshold.

48. The computer-readable memory of claim 47, wherein the first portion directing the computer to process with weak equalization is performed when the metric is greater than the predetermined threshold.

49. The computer-readable memory of claim 48, wherein the second portion directing the computer to process with strong equalization is preformed when the metric is less than the predetermined threshold.

50. The computer-readable memory of claim 47, wherein the second portion directing the computer to process with strong equalization is preformed when the metric is less than the predetermined threshold.

51. The computer-readable memory of claim 47, wherein the metric is obtain from a calculation of a sum of the squared errors during weak equalization.

52. The computer-readable memory of claim 39, wherein the predetermined criteria comprises a determination that an estimated energy-per-bit to noise ratio is greater that a predetermined value.

53. The computer-readable memory of claim 39, wherein the predetermined criteria comprises a determination that a metric obtained from the weak equalization is greater that a predetermined threshold.

54. The computer-readable memory of claim 39, further comprising a third portion for directing the computer to prefilter a received burst of data to produce samples for equalization.

55. The computer-readable memory of claim 39, wherein the weak equalization comprises decision feedback equalization.

56. The computer-readable memory of claim 39, wherein the strong equalization comprises at least one of maximum likelihood sequence estimator and delayed-decision-feedback sequence estimation.

57. The computer-readable memory of claim 39, further comprising a third portion for directing the computer to perform full turbo equalization using soft values fed-back from a decoder when the strong equalization fails.

58. A computer data signal embodied in a carrier wave, comprising instructions for:
directing a computer to process a first burst using weak equalization; and
directing the computer to process a subsequent burst using strong equalization when a predetermined criteria is met.
